(19) United States
(12) Patent Application Publication
(10) Pub. No.: US 2006/0107995 A1
(43) Pub. Date: May 25, 2006

(54) Thermophotovoltaic device

(76) Inventors: Gary Kovacik, Edmonton (CA); Lewis Fraas, Issaquah, WA (US); Chris Astle, Edmonton (CA)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(21) Appl. No.: 10/525,423

(22) PCT Filed: Aug. 22, 2003
(86) PCT No.: PCT/CA03/01295

§ 371 Date: Oct. 11, 2005

(30) Foreign Application Priority Data
Aug. 23, 2002 (CA) 2399673

(51) Int. Cl. H01L 31/00; H02N 6/00

(52) U.S. Cl. 136/253

(57) ABSTRACT

A thermophotovoltaic device (10) includes an energy source (12) compatible with thermophotovoltaic cells and thermophotovoltaic cells (14). A filter (16), adapted to filter out long wavelength energy, is positioned between the energy source (12) and the thermophotovoltaic cells (14). The filter (16) has dual walls (30 & 32) with a low conductivity space (34) between the walls (30 & 32) which is adapted to break the convection heat transfer path from the energy source (12) to the thermophotovoltaic cells (14).

### FIELD OF THE INVENTION

The present invention relates to a thermophotovoltaic device.

### BACKGROUND OF THE INVENTION

U.S. Pat. No. 5,403,405 (Fraas et al 1995), U.S. Pat. No. 5,551,992 (Fraas 1996), U.S. Pat. No. 5,753,050 (Charache et al 1998) are examples of thermophotovoltaic devices.

A problem experienced with thermophotovoltaic devices is that only a fraction of the energy generated can be used by the photovoltaic cells. Long wavelength energy can not be used by the photovoltaic cells and can increase cell temperature.

### SUMMARY OF THE INVENTION

What is required is a thermophotovoltaic device which is less susceptible to the detrimental effects of long wavelength energy.

According to the present invention there is provided a thermophotovoltaic device which includes an energy source compatible with thermophotovoltaic cells and thermophotovoltaic cells. A filter, adapted to filter out long wavelength energy, is positioned between the energy source and the thermophotovoltaic cells. The filter has dual walls with a low conductivity space between the walls which is adapted to break the convection heat transfer path from the energy source to the thermophotovoltaic cells.

The filter, as described above, filter out long wavelength energy, which the thermophotovoltaic cells are incapable of utilizing. The low conductivity space. preferably created by a vacuum, prevents heat transfer to the thermophotovoltaic cells. This makes the thermophotovoltaic cells may efficient, as will hereinafter be further described. The thermophotovoltaic calls can be made even more efficient, if a dielectric filter, adapted to filter mid-wavelength energy, is positioned between the energy source and the thermophotovoltaic cells.

### BRIEF DESCRIPTION OF THE DRAWINGS

These and other features of the invention will become more apparent from the following description in which reference is made to the appended drawings, the drawings are for the purpose of illustration only and are not intended to in any way limit the scope of the invention to the particular embodiment or embodiments shown, wherein:

FIG. 1 is a simplified block diagram of a thermophotovoltaic system.

FIG. 2 is a side elevation view of components for a thermophotovoltaic device constructed in accordance with the teachings of the present invention.

FIG. 3 is a side elevation view, in section, of a thermophotovoltaic device constructed in accordance with the teachings of the present invention.

### DETAILED DESCRIPTION OF THE PREFERRED EMBODIMENT

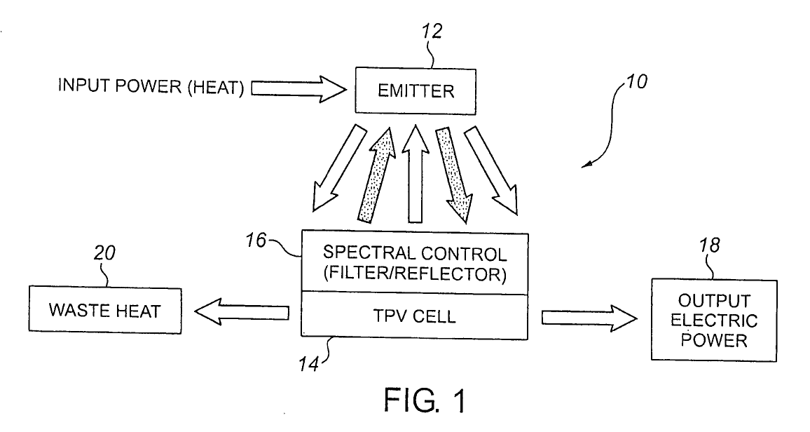

The preferred embodiment, a thermophotovoltaic device will now be described with reference to FIGS. 1 through 3.

Referring to FIG. 1. a thermophotovoltaic device, generally identified by reference numeral 10, includes an energy source 12 which is compatible with thermophotovoltaic cells and thermophotovoltaic cells 14. A filter 16 adapted to filter out long wavelength energy positioned between energy source 12 and thermophotovoltaic cells 14. Thermophotovoltaic cells 14 out put electric power, as indicated by labelled block 18 and waste heat, as indicated by labelled block 20.

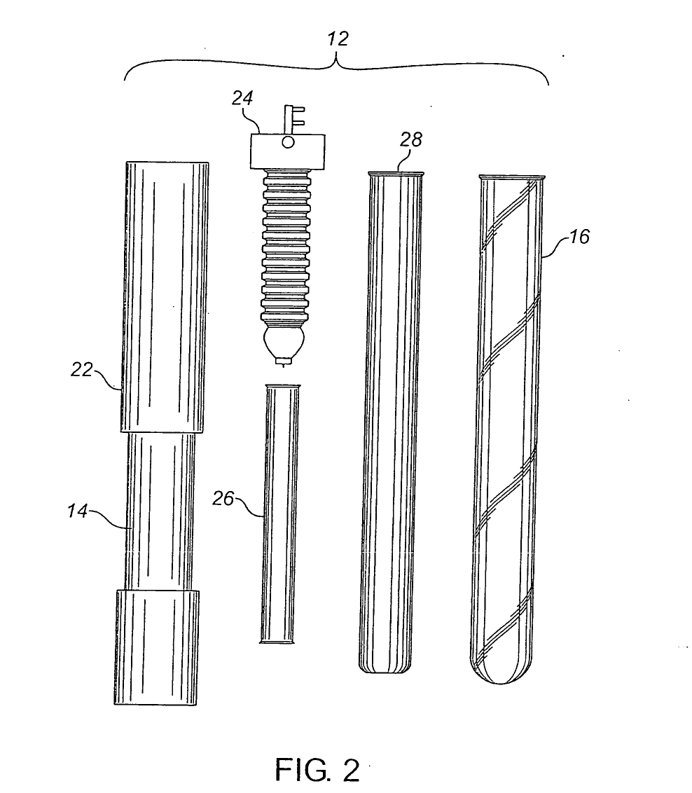

Referring to FIG. 2, the components of energy source 12 are shown. This includes an insulated burner emitter assembly housing 22, in which is positioned thermophotovoltaic cells 14. A burner 24 with internal SiC tube 26 and an overlying SiC emitter 28. Filter 16 is tubular and overlies SIC emitter 28.

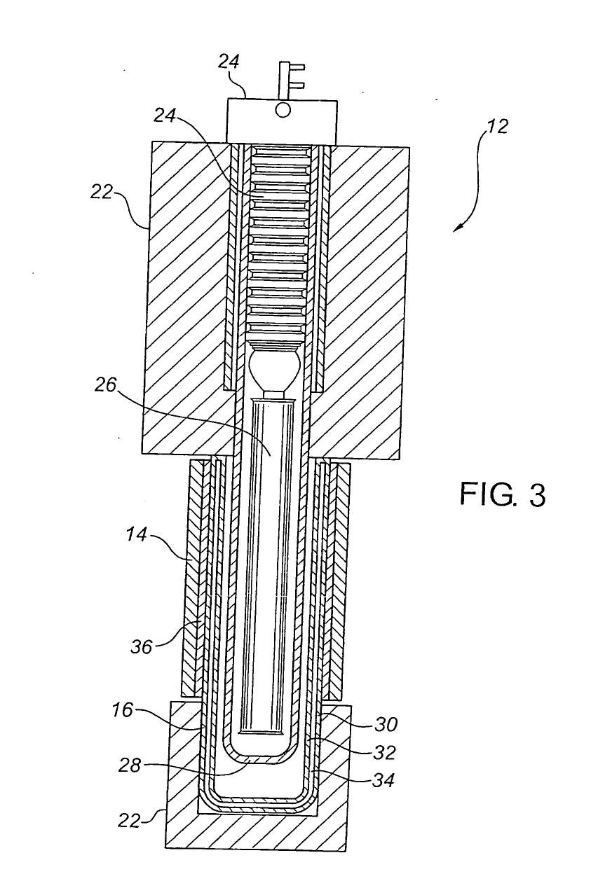

Referring to FIG. 3, filter 16 is made of concentric quartz glass tubing and has dual walls 30 and 32 with a low conductivity space 34 positioned between walls 30 and 32. Low conductivity can be created in space 34 by various means, preferably, by placing the space under vacuum. Low conductivity space 34 is adapted to break the convection heat transfer path from energy source 12 to thermophotovoltaic cells 14.

In order to further increase the efficiency of the device, a dielectric filter 36 is provided. Dielectric filter 36 is adapted to filter mid-wavelength energy positioned between energy source 12 and thermophotovoltaic cells 14.

TPV systems consist of a heat source above about 1300 K, Coupled with a broadband or selective emitter, thermophotovoltaic converter cells with or without a filter/reflector, and a cooling and heat recuperation system. Some attractions of this technology are.

High power densities −1 −2 W/cm² are reported in prototype systems. Mature systems expected to be on the order of 5 W/cm².

Quiet Operation—TPV conversion uses no moving parts (except cooling or combustion air fans in some designs) and can be expected to be essentially silent. This feature makes it attractive for military applications and recreational use.

Low Maintenance—due to lack of moving parts maintenance requirements will be minimal.

Cogeneration—for high efficiency, TPV systems must include a heat recovery system as a part of cell cooling and to preheat fuel and air before combustion. TPV devices are an excellent candidate for combined heat and power applications.

Versatility—TPV systems may be fuelled by almost any combustible material, although the burner must be designed for that particular fuel in order to maintain high efficiency.

Low emissions—are possible with well-designed burner/fuel selection.

A simplified TPV system schematic is shown in FIG. 1.

Typical TPV units can include some or all of the following subsystems:

1. Energy source 12—a burner for efficient combustion of the fuel, be it liquid or gaseous, hydrocarbon, or even biomass. The burner design for TPV is not trivial due to relatively low firing rates, high operating temperatures, small size, uniform temperature distribution and high efficiency requirements. The burner may also have means of recirculating exhaust gases in order to preheat fuel and combustion air to increase combustion efficiency.

2. Emitter—an IR radiation source (heated by the combustion) operating in the temperature range of 1300 K to 1800 K. Temperatures below this can lead to low power densities and low electrical output, while operation above the maximum is not practical due to cost of high temperature materials and problems with cell cooling. The emitter material must have mechanical strength at the operating temperature, high emissivity and tolerance for thermal cycling. There are generally two types of radiators used:

Broadband emitters—basically a black body, behaving according to Planck radiation law, where radiation extends across a wide wavelength range. Only a fraction of energy (dependent on temperature) is radiated below 2.5 μm (equivalent to energy bandgap of 0.5 eV) and can be used effectively by photovoltaic cell. The remaining long wave energy (photons) is not used by the cells and can increase cell temperature. Ideally this energy is recycled back to the radiation or used to preheat the inlet fuel and air. The most commonly used broadband emitter material is silicon carbide (SIC). SIC is an excellent infrared emitter material with high emissivity, good thermal conductivity and relatively (food thermal shock resistance. At a temperature of 1800 K silicon carbide has a radiation emission peak between 1.4 and 1.6 μm.

Selective emitters—certain rare earth oxides (ytterbium, erbium, holmium) radiate in a fairly narrow band of wavelengths. The major disadvantages of these emitters are low power density due to very narrow emission bandwidths and low average peak emittance. A solution to these problems would be to increase emitter temperature, but this leads to shorter material life and lower fuel to radiant power conversion efficiency. There is also significant radiation of wavelengths longer than 3 μm and an IR filter should be used to reflect these low energy level photons back to the emitter. Variations of selective emitter design Include:

matched emitters consisting of ceramic matrix composites with a refractory oxide (such as alumina, magnesia oxide or spinel) doped with a d-series transition element. Relatively broad IR emission spectrum in the range 1.0 to 1.7 μm has been reported. This is easier to match with usable bandwidth of GaSb TPV cells. Another type of selective emitter uses a microstructured tungsten surface with low emittance in the region above 2 μm. Tungsten is very stable at high temperatures in a vacuum, but oxidizes in air so it is necessary to operate this type of emitter in vacuum or in inert gas atmospheres.

multiband emitters built as a combination of two rare oxides, such as Er₂O₃/Ho₂O₃ and Er₂O₃/Yb₂,O₃ resulting in multiple peak spectrum radiation. One of the manufacturing methods for these emitters is a thermal plasma spray of a thin film onto various substrates (SIC or suitable ceramic oxide with reflective metal backing, or reflective metal layer deposited on front of oxide substrate).

3. IR filter—for optimum system efficiency, the incident radiation should match the recombination spectrum of the photocell material. Excess energy should be reflected back to the emitter and preferably reabsorbed. To achieve this, single or multiple filters are placed between the emitter and the TPV cells. They may be integrated with the TPV cell assembly. There are a number of different filter designs:

Interference or mesh filters similar to those used for microwave frequencies. Generally the dimensions of the array elements are a fraction of a wavelength requiring resolution less than 0.2 μm. The state of the art conventional lithography is now about 0.1 μm feature size. This allows mass manufacturing of the filter at costs probably lower than a dielectric stack. The mesh filters use Au as a base metal deposited on a dielectric substrate and as such have good IR reflectivity (>95%) at wavelengths longer than 2 μm.

Multilayer dielectric filters are based on interference effects, using multiple layers of dielectric films with varing refraction coefficients and different thicknesses. Dielectric films have minimal losses and it is possible to manufacture a filter with specific performance by increasing, the number of layers.

4. TPV cells are narrow bandgap (0.5 to 0.7 eV) III-V semiconductor diodes that convert photons radiated from a thermal radiation source (at temperatures below 2000K) into electricity. Photons with energy greater than the semiconductor bandgap excite electrons from the valence band to the conduction band. The created electron-hole pairs are then collected by metal electrodes and can be utilized to power external loads.

The invention described here is an improved filter system to recycle a large fraction of the longer wavelength energy to the emitter while reducing the convective heat transfer from the emitter to the TPV cells. The concept is to combine dielectric filters (as described above) that are positioned directly on or in front of the TPV cell arrays with a dual quartz glass tube filter with the space between the quartz tubes evacuated to break the convection path. The dielectric filters provide recycling of mid-wavelength energy (up to about 3.5 micron wavelength) while the quartz glass recycles the longer wavelengths and the addition of the vacuum layer breaks the convection heat transfer path from the emitter to the cell arrays. This arrangement should provide a simple and inexpensive method of improving TPV system efficiency by reducing energy losses.

A sketch of the basic components of the TPV system as conceived is given in FIG. 2. FIG. 3 shows a cut-away view of the assembled system.

Use WS radiant tube burner with double wall GE 214 low OH fused silica thermos to reduce long wavelength IR by one third via 1/(n+1) heat shield formula (with n=2 and assuming near planar geometry). Also use dielectric filters from JXC for mid wavelength band spectral control.

Given an energy rate transfer budget of 7 W/cm2, we make the following, efficiency calculation.

Assume emitter temperature of 1100 C. or 1373 K.

Total Black Body power=20.15 W/cm2.

% power from Black Body for wavelength<1.8 microns=15%.

% power from Black Body between 1.8 and 3.6 microns=48%

% power from BB for wavelengths longer than 3.6 microns=37%

Power to receiver from various bands:

Less than 1.8 microns=15%×20.15=3.02 W/′cm2

Between 1.8 to 3.6 microns=10%×48%×20.15=0.97 W/cm2

(assumes 90% dielectric filter recycling)

Greater than 3.6 microns=33%×37%×20.15=2.46 W/cm2

Total net power transferred from emitter=6.45 W/cm2

Spectral efficiency=3.02/6.45=47%

System electrical efficiency=75%×30%×47%=10.6%

Where 75% is chemical to radiation efficiency

And 30% is PV cell conversion efficiency.

Assume 80 mm diameter emitter and 250 mm long cell array,

Then emitter area will be 3.14×8×25=628 cm2.

Given 1 W(electric)/cm2, potential electrical output could be 600 W. This corresponds to a 6 kW(thermal) burner which is in the operating range of the WS C80/800 burner.

The benefit of the evacuated quartz tube (in addition to long, wave recycling) is that it will reduce convective heat transfer from the emitter to the cell arrays as demonstrated in the calculations below.

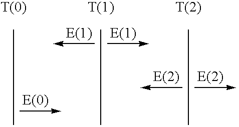

Calculate quartz shield temperatures given emitter at 1100 C

Note that E(0)=E(2)=2 E(1) and E(1) and E(1)=2 E(2) from the energy balance at each quartz shield.

Therefore E(O)=4 E(2)−E(2)=3 E(2)

Assuming T(O)=1100 C

Then E(0) 37%×20 W/cm2=7.4 W/cm2

And E(2)=(⅓))×7.4=2.47 W/cm2

Also [T(2)/T(0)]⁴=2.47/20=0.124

Therefore T(2)=0.593×1373=814 K=541 C

And similarly T(1)=0.71 T(0)=969 K=696 C

Thus, instead of convective/conductive transfer in the air layer between the 1100 C emitter and the ˜30 C cells the quartz tube will transfer heat from the second quartz glass at ˜541 C to the TPV cells. This could reduce the heat loss through the cells by about 50%

### The Effect of a Double-Walled Quartz Cylinder on Burner Emissive Power in a Thermophotovoltaic Power Generation System

### EXAMPLE I

### With Dielectric Filters Without Quartz Tubes Installed

Data taken after system was fired at 12 kW for 50 minutes.

Middle hole burner temperature—937° C.

Bottom hole burner temperature—1006° C.

Average Temperature—971.5° C.

Total Black Body Power 5.67×10⁻⁸×(971.5+273.15)⁴=13.6 W/cm²

### With Quartz Tube Filters Installed

Data taken after system was fired at 12 kW for 50 minutes.

Middle hole burner temperature—1001° C.

Bottom hole burner temperature—1069° C.

Average Temperature=1035° C.

Total Black Body Power=5.67×10⁻⁸×(1035+273.5)⁴=16.6 W/cm²

### Average Power Increase Due to Quartz Tubes=16.6−13.6/13.6×100%=22%

### EXAMPLE 2

Without Dielectric Filters Without Quartz Tubes Installed

Data taken after system was fired at 12 kW for 1 hr.

Burner—temp in inferred from current vs. temperature plot—71° C. (middle hole)

Total Black Body Power=5.67×10⁻⁸×(710÷273.1 5)⁴=5.3 W/cm²

### With Quartz Tube Filters Installed

Data taken after system was fired at 12 kW for 1 hr.

Burner temp interred from current vs. temperature plot—800° C. (middle hole)

Total Black Body Power=5.67×10⁻⁸×(800+273.15)⁴=7.5 W/cm²

Average Power increase due to quartz tubes=7.5−5.3/5.3×100%=42%

The embodiments of the invention in which an exclusive property or privilege is claimed are defined as follows:

1. In a thermophotovoltaic device (10) having an energy source (12) compatible with thermophotovoltaic cells and thermophotovoltaic cells (14), the improvement comprising:
a filter (16) adapted to filter out long wavelength energy positioned between the energy source and the thermophotovoltaic cells, the filter (16) having dual walls (30 & 32) with a low conductivity space (34) that is evacuated to place it under vacuum between the walls which is adapted to break the convection heat transfer path from the energy source (12) to the thermophotovoltaic cells (14).

2. The thermovoltaic device as defined in claim 1, further including a dielectric filter (36) adapted to filter mid-wavelength energy positioned between the energy source (12) and the thermophotovoltaic cells (14).

3. The thermovoltaic device as defined in claim 1, wherein the dual walls (30 & 32) are of heat resistant glass.

4. The thermovoltaic device as defined in claim 4, wherein the heat resistant glass is quartz.

5. The thermovoltaic device as defined in claim 4, dual walls (30 & 32) are arranged as concentric tubes.

6. The thermovoltaic device as defined in claim 1, the energy source being a burner with an emitter (22, 24, 26, 28).
